(19) United States
(12) Patent Application Publication
(10) Pub. No.: US 2023/0194563 A1
(43) Pub. Date: Jun. 22, 2023

(54) INERTIAL MEASUREMENT DEVICE

(71) Applicant: SEIKO EPSON CORPORATION, Tokyo (JP)

(72) Inventors: Toru Watanabe, Matsumoto-shi (JP); Masayasu Sakuma, Shiojiri-shi (JP); Hiroki Matsuoka, Suwa-gun Fujimi-machi (JP)

(21) Appl. No.: 18/085,197

(22) Filed: Dec. 20, 2022

(30) Foreign Application Priority Data
Dec. 22, 2021 (JP) 2021-207922

(51) Int. Cl. G01P 15/08; G01P 1/02; G01P 1/12; H05K 5/00; H05K 5/06

(52) U.S. Cl. CPC G01P 15/0802; G01P 1/12; G01P 1/023; H05K 5/069; H05K 5/0095

(57) ABSTRACT

An inertial measurement device includes: a first inertial sensor; a first inertial sensor module in which the first inertial sensor is stored in a first package made of resin; a base having a concave portion and made of ceramic; and a lid body. The first inertial sensor module is accommodated in an accommodation space between the base and the lid body and is hermetically sealed.

The present application is based on, and claims priority from JP Application Serial Number 2021-207922, filed Dec. 22, 2021, the disclosure of which is hereby incorporated by reference herein in its entirety.

### BACKGROUND

### 1. Technical Field

The present disclosure relates to an inertial measurement device.

### 2. Related Art

An inertial measurement device including an inertial sensor module having an inertial sensor such as an acceleration sensor or an angular velocity sensor is known. The inertial measurement device is incorporated in various electronic devices or machines, or is mounted on a moving body such as an automobile, and is used to monitor an inertial amount such as an acceleration or an angular velocity.

For example, JP-A-2017-49122 discloses a sensor unit including a sensor device. The sensor device includes an inertial sensor resin-sealed with a sealing resin.

When moisture enters the sealing resin from the outside, stress of the sealing resin may vary. When the stress of the sealing resin varies, the inertial sensor may be deformed, which may affect the measurement of the sensor device. That is, there is a need for an inertial measurement device that reduces the effect of moisture and has excellent detection accuracy.

### SUMMARY

An inertial measurement device according to an aspect of the present application includes: a first inertial sensor; a first inertial sensor module in which the first inertial sensor is stored in a first package made of resin; a base having a concave portion and made of ceramic; and a lid body. The first inertial sensor module is accommodated in an accommodation space between the base and the lid body and is hermetically sealed.

### BRIEF DESCRIPTION OF THE DRAWINGS

FIG. 1 is a plan view of an inertial measurement device according to a first embodiment.

FIG. 2 is a cross-sectional view of the inertial measurement device.

FIG. 3 is an exploded perspective view showing a method for manufacturing the inertial measurement device.

FIG. 4 is a plan view of a first inertial sensor module.

FIG. 5 is a cross-sectional view taken along a line A-A in FIG. 4.

FIG. 6 is a cross-sectional view taken along a line B-B in FIG. 4.

FIG. 7 is a cross-sectional view of an inertial measurement device in a different mounting form according to a second embodiment.

FIG. 8 is a cross-sectional view of an inertial measurement device in a different mounting form.

FIG. 9 is a transparent plan view of an inertial measurement device in a different mounting form.

FIG. 10 is a transparent plan view of an inertial measurement device in a different mounting form.

FIG. 11 is a plan view of an inertial measurement device in a different form according to a third embodiment.

FIG. 12 is a cross-sectional view of the inertial measurement device in the different form.

FIG. 13 is a transparent plan view of a second inertial sensor module.

FIG. 14 is a cross-sectional view of the second inertial sensor module.

FIG. 15 is an exploded perspective view of an inertial measurement device in a different form according to a fourth embodiment.

### DESCRIPTION OF EXEMPLARY EMBODIMENTS

### First Embodiment

### Outline of Inertial Measurement Device

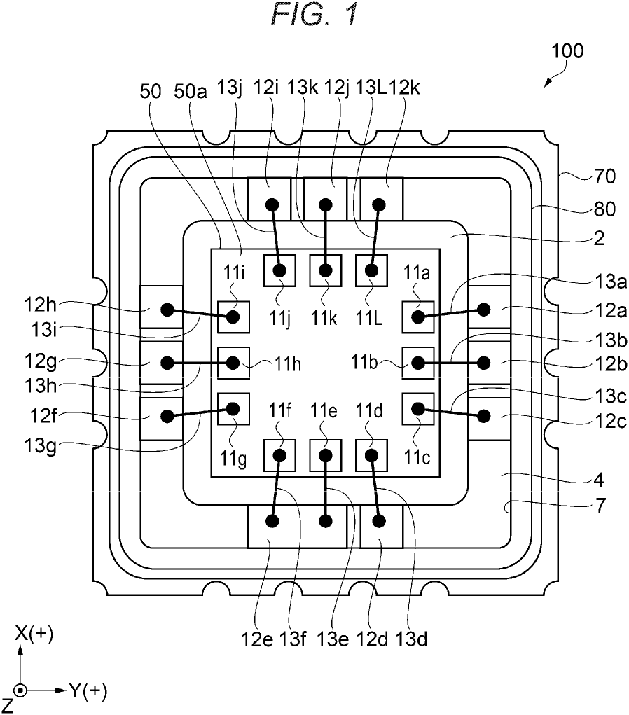

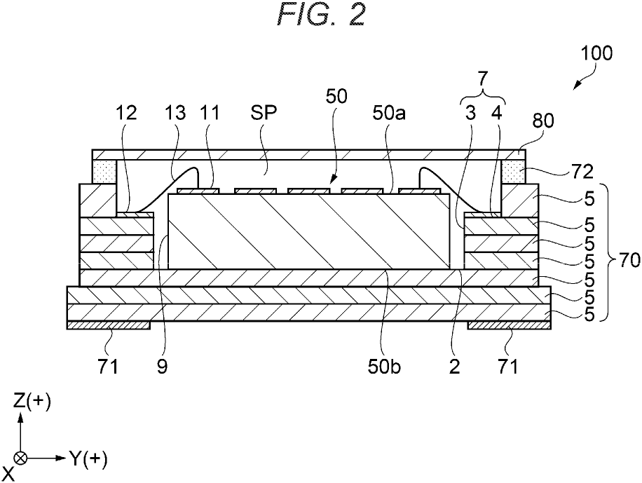

FIG. 1 is a plan view showing an outline of an inertial measurement device. FIG. 2 is a cross-sectional view of the inertial measurement device.

First, a schematic configuration of an inertial measurement device 100 according to the present embodiment will be described with reference to FIGS. 1 and 2. In the drawings, an X axis, a Y axis, and a Z axis are shown as three axes orthogonal to one another. In the present specification, a first axis is the X axis, a second axis is the Y axis, and a third axis is the Z axis. A direction along the X axis is referred to as an “X direction”. A direction along the Y axis is referred to as a “Y direction” . A direction along the Z axis is referred to as a “Z direction”. Further, a tip end side of an arrow in each axis direction is also referred to as a “plus side”, a base end side is also referred to as a “minus side”, a plus side in the Z direction is also referred to as “upper”, and a minus side in the Z direction is also referred to as “lower”. The Z direction is along a vertical direction. An XY plane is along a horizontal plane. A plus direction and a minus direction are also collectively referred to as the X direction, the Y direction, and the Z direction.

The inertial measurement device 100 in the present embodiment includes a first inertial sensor module 50, a base 70, a lid 80, and the like.

The first inertial sensor module 50 is, for example, a six-axis combo sensor including a three-axis gyro sensor and a three-axis acceleration sensor. As a sensor element of each axis, a sensor element manufactured by processing a silicon substrate using a micro electro mechanical system (MEMS) technique is used. The first inertial sensor module 50 has a flat rectangular parallelepiped shape. As shown in FIG. 1, a plurality of electrode terminals 11 are provided at a first surface 50a. An exterior of the first inertial sensor module 50 is resin-molded. Details of the first inertial sensor module 50 will be described later.

In a preferable example, the base 70 is a ceramic container having a substantially rectangular shape in a plan view, and is formed by stacking a plurality of ceramic substrates 5, as shown in FIG. 2.

The base 70 has a concave portion 7 substantially at the center of the base 70. The first inertial sensor module 50 is mounted on a placement surface 2 serving as the bottom portion of the concave portion 7. In other words, the first inertial sensor module 50 is mounted on the placement surface 2 in a state in which a second surface 50b, which is an opposite-side surface from a first surface 50a, faces the concave portion 7. The concave portion 7 includes an accommodation portion 3 having the placement surface 2 as the bottom portion, and a peripheral edge portion 4 that is one step higher than the placement surface 2 and that surrounds the accommodation portion 3. A plurality of coupling terminals 12 corresponding to the plurality of electrode terminals 11 in the first inertial sensor module 50 are provided in the peripheral edge portion 4.

As shown in FIG. 1, the electrode terminals 11 of the first inertial sensor module 50 and the coupling terminals 12 of the peripheral edge portion 4 are coupled by bonding wires 13. Hereinafter, a detailed description will be given by assigning a branch number to each individual portion.

Three electrode terminals 11a to 11c are provided along a side of the first inertial sensor module 50 on a Y-plus side. Three coupling terminals 12a to 12c are provided along a side of the peripheral edge portion 4 on the Y-plus side. The electrode terminal 11a is electrically coupled to the coupling terminal 12a by a bonding wire 13a. The electrode terminal 11b is electrically coupled to the coupling terminal 12b by a bonding wire 13b. The electrode terminal 11c is electrically coupled to the coupling terminal 12c by a bonding wire 13c.

Three electrode terminals 11d to 11f are provided along a side of the first inertial sensor module 50 on an X-minus side. Two coupling terminals 12d and 12e are provided along a side of the peripheral edge portion 4 on the X-minus side. The electrode terminal 11d is electrically coupled to the coupling terminal 12d by a bonding wire 13d. The coupling terminal 12e is longer than the coupling terminal 12d. The electrode terminals 11e and 11f are both electrically coupled to the coupling terminal 12e by bonding wires 13e and 13f.

Three electrode terminals 11g to 11i are provided along a side of the first inertial sensor module 50 on a Y-minus side. Three coupling terminals 12f to 12h are provided along a side of the peripheral edge portion 4 on the Y-minus side. The electrode terminal 11g is electrically coupled to the coupling terminal 12f by a bonding wire 13g. The electrode terminal 11h is electrically coupled to the coupling terminal 12g by a bonding wire 13h. The electrode terminal 11i is electrically coupled to the coupling terminal 12h by a bonding wire 13i.

Three electrode terminals 11j, 11k, and 11L are provided along a side of the first inertial sensor module 50 on an X-plus side. Three coupling terminals 12i to 12k are provided along a side of the peripheral edge portion 4 on the X-plus side. The electrode terminal 11j is electrically coupled to the coupling terminal 12i by a bonding wire 13j. The electrode terminal 11k is electrically coupled to the coupling terminal 12j by a bonding wire 13k. The electrode terminal 11L is electrically coupled to the coupling terminal 12k by a bonding wire 13L.

The coupling terminals 12 of the peripheral edge portion 4 are electrically coupled to mounting terminals 71 (FIG. 2) provided at a bottom surface of the base 70 by wirings, which are not shown, in the base 70. Although two mounting terminals 71 are shown in FIG. 2, the mounting terminals 71 whose number corresponds to the number of coupling terminals 12a to 12k are actually provided.

The lid 80 is a lid body and seals an upper surface of the base 70 in a state in which the first inertial sensor module 50 is mounted. In the plan view, the lid 80 has a substantially rectangular shape conforming to the base 70. As a material of the lid 80, Kovar is employed as a preferable example. The material is not limited to Kovar, and a metal such as 42 alloy, aluminum, copper, or duralumin, or an alloy containing any of these may be used. The lid 80 is bonded to the base 70 via a bonding member 72. In the preferable example, gold is used as the bonding member 72, and the base 70 and the lid 80 are bonded by seam welding by thermocompression bonding of gold. At this time, it is preferable that the bonding member 72 is melted by Joule heat to be in fusion contact with the lid 80 by applying pressure and current from above the lid 80 using a roller electrode. The material is not limited to gold, and any metal or alloy may be used as long as it is diffusion-bonded between the bonding member 72 and the base 70 and between the bonding member 72 and the lid 80 to ensure electrical conduction between the base 70 and the lid 80. The welding is not limited to the seam welding, and a pressure welding technique can be applied in which a base material is mechanically melted and bonded by friction, pressure, current, or the like.

The technique is not limited to pressure welding technique including the seam welding, and it is sufficient that the base 70 and the lid 80 can be welded so as to be in an airtight sealed state. For example, a fusion bonding technique of melting and bonding a base material by laser irradiation or the like may be used, or a brazing technique of brazing two components with a welding material such as a brazing material may be used to bond the two components together.

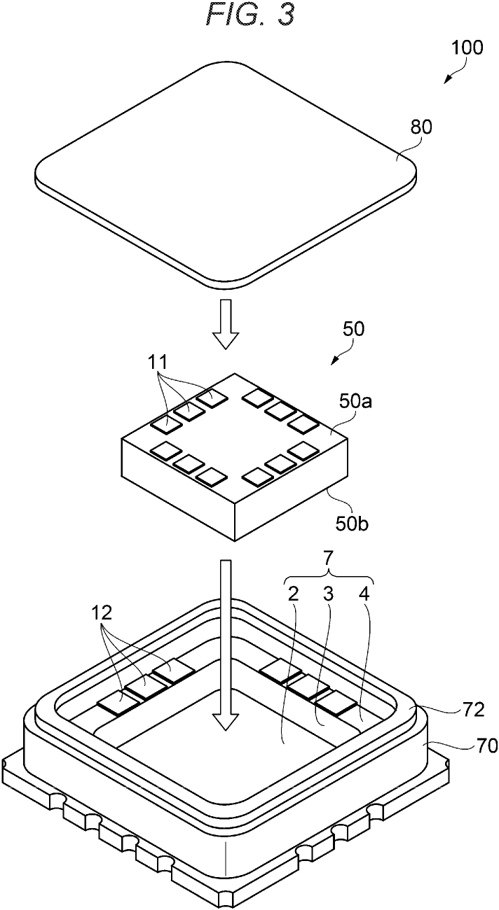

FIG. 3 is an exploded perspective view showing a method for manufacturing the inertial measurement device.

First, as shown in FIG. 3, the first inertial sensor module 50 is mounted on the placement surface 2 of the accommodation portion 3 on the base 70. Specifically, the first inertial sensor module 50 is mounted on the placement surface 2 with the second surface 50b of the first inertial sensor module 50 facing the concave portion 7. At this time, an adhesive such as a silver paste or a solder paste is applied to the placement surface 2 in advance. After the first inertial sensor module 50 is placed, die attach is completed by heating and curing the adhesive.

Next, the electrode terminals 11 of the first inertial sensor module 50 and the coupling terminals 12 of the peripheral edge portion 4 are coupled by the bonding wires 13.

Finally, the lid 80 is bonded to the base 70. In the preferable example, the lid 80 is bonded to the base 70 in a depressurized environment. The bonding member 72 is set in advance at a peripheral edge portion of the base 70.

Accordingly, as shown in FIG. 2, the inside of an accommodation space SP between the base 70 and the lid 80 is hermetically sealed in a depressurized state. The inside of the accommodation space SP may be hermetically sealed in an inert gas atmosphere. In other words, the first inertial sensor module 50 is accommodated in the accommodation space SP between the base 70 and the lid 80 and is hermetically sealed.

### Outline of First Inertial Sensor Module

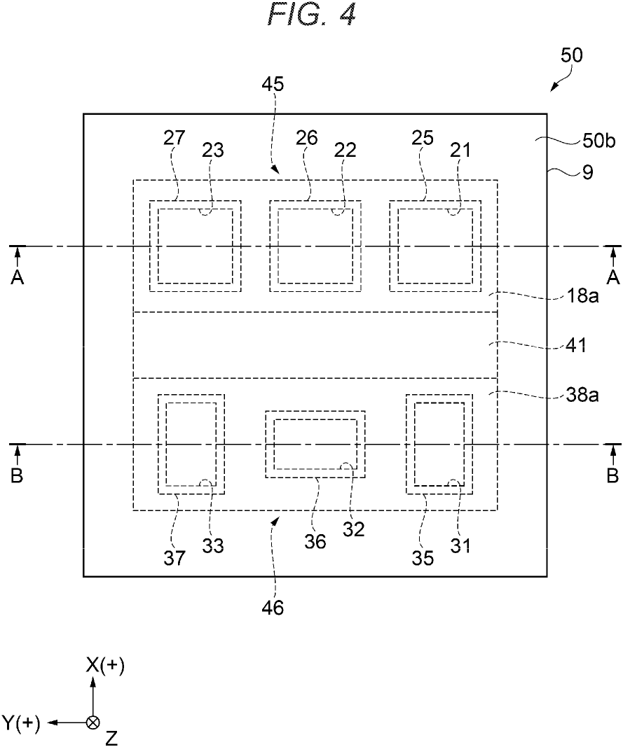

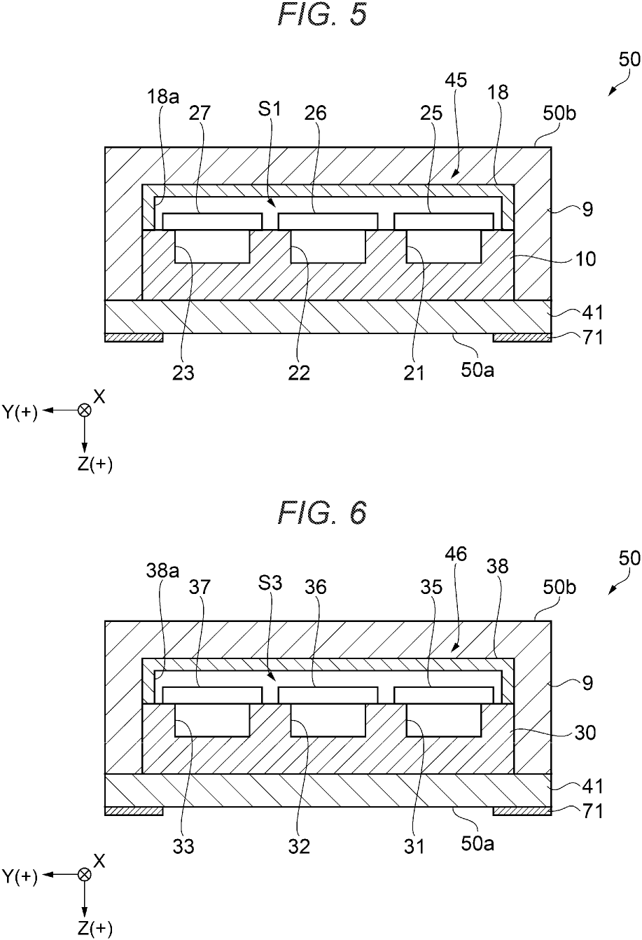

FIG. 4 is a transparent plan view showing an outline of the first inertial sensor module. FIG. 5 is a cross-sectional view taken along a line A-A in FIG. 4. FIG. 6 is a cross-sectional view taken along a line B-B in FIG. 4.

FIG. 4 is a transparent plan view of the first inertial sensor module 50 as viewed from a second surface 50b side. As shown in FIG. 4, the first inertial sensor module 50 includes a first inertial sensor 45 and a third inertial sensor 46 that are disposed on a base plate 41. The base plate 41 is a substrate at which two sensors are placed.

As shown in FIG. 5, the first inertial sensor 45 includes a substrate 10, a lid body 18, a first gyro sensor element 25, a second gyro sensor element 26, and a third gyro sensor element 27. The first gyro sensor element 25, the second gyro sensor element 26, and the third gyro sensor element 27 are accommodated in an accommodation space S1 formed by the substrate 10 and the lid body 18. The accommodation space S1 is an airtight space, and is in a depressurized state, preferably in a state close to a vacuum state.

In the first inertial sensor 45, the first gyro sensor element 25 detects an angular velocity around the X axis, the second gyro sensor element 26 detects an angular velocity around the Y axis, and the third gyro sensor element 27 detects an angular velocity around the Z axis. The first gyro sensor element 25, the second gyro sensor element 26, and the third gyro sensor element 27 are gyro sensor elements manufactured by processing a silicon substrate using the MEMS technique, and detect the angular velocity based on a change in capacitance between a movable electrode and a fixed electrode.

Three concave portions 21, 22, and 23 are formed in the substrate 10, and the first gyro sensor element 25, the second gyro sensor element 26, and the third gyro sensor element 27 are disposed on the substrate 10 in a manner of corresponding to the concave portions 21, 22, and 23, respectively. The concave portions 21, 22, and 23 function as escape portions for preventing contact between the first gyro sensor element 25, the second gyro sensor element 26, and the third gyro sensor element 27 and the substrate 10, respectively.

The substrate 10 is a silicon substrate. The substrate 10 may be a substrate formed of a glass material containing alkali metal ions, for example, Pyrex (registered trademark) glass as a main material. By a step conforming to a silicon semiconductor process, a sensor structure is formed of a material such as polysilicon on the substrate 10. The sensor structure according to the embodiment includes the first gyro sensor element 25, the second gyro sensor element 26, and the third gyro sensor element 27.

A concave portion 18a is formed in the lid body 18, and the accommodation space S1 is formed by bonding the lid body 18 to the substrate 10, and the first gyro sensor element 25, the second gyro sensor element 26, and the third gyro sensor element 27 are accommodated in the accommodation space S1. The concave portion 18a faces the three concave portions 21, 22, and 23 in the substrate 10. In the present embodiment, the lid body 18 is formed of a silicon substrate. A glass frit or the like is used for bonding the substrate 10 and the lid body 18, and the sensor structure is finally hermetically sealed with respect to the outside air. A configuration of the sensor device described above is an example, and other examples may be used. For example, the gyro sensor may have a structure in which a drive unit is common and only a detection unit is divided for each axis.

The description returns to FIG. 4.

The third inertial sensor 46 includes a first acceleration sensor element 35, a second acceleration sensor element 36, and a third acceleration sensor element 37, and is a three-axis acceleration sensor that can measure accelerations in detection axes including the X direction as a first axis, the Y direction as a second axis, and the Z direction as a third axis. The first acceleration sensor element 35, the second acceleration sensor element 36, and the third acceleration sensor element 37 are acceleration sensor elements manufactured using the MEMS technique, and detect the acceleration based on a change in capacitance between the movable electrode and the fixed electrode. In other words, the first inertial sensor module 50 includes the third inertial sensor 46 that detects a physical quantity different from a physical quantity detected by the first inertial sensor 45.

As shown in FIG. 6, the third inertial sensor 46 includes a substrate 30, a lid body 38, the first acceleration sensor element 35, the second acceleration sensor element 36, and the third acceleration sensor element 37. The first acceleration sensor element 35, the second acceleration sensor element 36, and the third acceleration sensor element 37 are accommodated in an accommodation space S3 formed by the substrate 30 and the lid body 38. The accommodation space S3 is an airtight space in which an inert gas such as nitrogen, helium, or argon is sealed. It is preferable that the accommodation space S3 has a use temperature of about -40° C. to 125° C., and has a substantially atmospheric pressure. However, an atmosphere of the accommodation space S3 is not particularly limited, and may be, for example, a depressurized state or a pressurized state. The substrate 10 is separate from the substrate 30, and may be integrated with the substrate 30. That is, the first gyro sensor element 25, the second gyro sensor element 26, the third gyro sensor element 27, the first acceleration sensor element 35, the second acceleration sensor element 36, and the third acceleration sensor element 37 may be formed on one substrate, for example, the substrate 10.

In the third inertial sensor 46, the first acceleration sensor element 35 detects an acceleration in the X direction. The second acceleration sensor element 36 detects an acceleration in the Y direction. The third acceleration sensor element 37 detects an acceleration in the Z direction.

Three concave portions 31, 32, and 33 are formed in the substrate 30, and the first acceleration sensor element 35, the second acceleration sensor element 36, and the third acceleration sensor element 37 are disposed on the substrate 30 in a manner of corresponding to the concave portion 31, the concave portion 32, and the concave portion 33, respectively. The concave portions 31, 32, and 33 function as escape portions for preventing contact between the first acceleration sensor element 35, the second acceleration sensor element 36, and the third acceleration sensor element 37 and the substrate 30, respectively.

The substrate 30 is a silicon substrate. The substrate 30 may be a substrate formed of a glass material containing alkali metal ions, for example, Pyrex (registered trademark) glass as a main material. By a step conforming to a silicon semiconductor process, a sensor structure is formed of a material such as polysilicon on the substrate 30. The sensor structure according to the embodiment includes the first acceleration sensor element 35, the second acceleration sensor element 36, and the third acceleration sensor element 37.

A concave portion 38a is formed in the lid body 38, the accommodation space S3 is formed by bonding the lid body 38 to the substrate 30, and the first acceleration sensor element 35, the second acceleration sensor element 36, and the third acceleration sensor element 37 are accommodated in the accommodation space S3. The concave portion 38a faces the three concave portions 31, 32, and 33 in the substrate 30. In the present embodiment, the lid body 38 is formed of a silicon substrate. Accordingly, the lid body 38 and the substrate 30 can be firmly bonded by anodic bonding. A glass frit or the like is used for bonding the substrate 30 and the lid body 38, and the sensor structure is finally hermetically sealed with respect to the outside air. A configuration of the sensor device described above is an example, and other examples may be used.

The description returns to FIG. 4.

The first inertial sensor module 50 is a six-axis combo sensor including the first inertial sensor 45, which is a three-axis gyro sensor, and the third inertial sensor 46, which is a three-axis acceleration sensor. A periphery of the first inertial sensor module 50 is covered with a resin 9. The resin 9 is, for example, an epoxy resin. The exterior of the first inertial sensor module 50 is resin-molded with the resin 9. In other words, the first inertial sensor module 50 is resin-molded by the resin 9 as a first package. The third inertial sensor 46 is stored in the first package together with the first inertial sensor 45.

Here, according to verification by inventors, it is confirmed that when the first inertial sensor module 50 is used as it is, for example, when humidity of the use environment varies, an amount of moisture corresponding to the varied humidity is adsorbed in the resin mold, and a residual stress inside the resin 9 changes. The stress change causes a variation in stress constantly applied to the sensor element, thereby causing a variation in sensor characteristics.

In the present embodiment, two sensors, that is, the first inertial sensor 45 of the three-axis gyro sensor and the third inertial sensor 46 of the three-axis acceleration sensor are mounted as the first inertial sensor module 50. The configuration is not limited thereto, and either one of the first inertial sensor 45 and the third inertial sensor 46 may be mounted.

As described above, according to the inertial measurement device 100 in the present embodiment, the following effects can be attained.

The inertial measurement device 100 includes the first inertial sensor 45, the first inertial sensor module 50 in which the first inertial sensor 45 is stored in the resin 9, the base 70 that has the concave portion 7 and that is made of ceramic, and the lid 80. The resin 9 is the first package made of resin. The first inertial sensor module 50 is accommodated in the accommodation space SP between the base 70 and the lid 80 and is hermetically sealed.

Accordingly, the first inertial sensor module 50 is hermetically sealed in the accommodation space SP between the ceramic base 70 and the metal lid 80. In other words, the first inertial sensor module 50 can be hermetically sealed in a ceramic package that can reliably prevent moisture from entering.

Therefore, since it is possible to reliably prevent moisture from entering the inertial measurement device 100, it is possible to prevent stress variation of the resin 9 due to moisture entering.

Therefore, it is possible to provide the inertial measurement device 100 that reduces the influence of moisture and that has excellent detection accuracy.

The base 70 and the lid 80 are bonded by welding.

Accordingly, since the base 70 and the lid 80 can be firmly bonded by welding, the inside of the package can be reliably hermetically sealed.

The first inertial sensor module 50 has the first surface 50a including the plurality of electrode terminals 11 and the second surface 50b which is an opposite-side surface from the first surface 50a. The concave portion 7 includes the accommodation portion 3 having the placement surface 2 as the bottom portion and the peripheral edge portion 4 that is one step higher than the placement surface 2 and that surrounds the accommodation portion 3. The first inertial sensor module 50 is mounted on the placement surface 2 in a state in which the second surface 50b faces the concave portion 7. The peripheral edge portion 4 is provided with the coupling terminals 12 corresponding to the electrode terminals 11. The electrode terminals 11 and the coupling terminals 12 of the peripheral edge portion 4 are coupled to each other by the bonding wires 13.

Accordingly, the first inertial sensor module 50 and the base 70 can be electrically coupled by the bonding wires 13.

The first inertial sensor module 50 further includes the third inertial sensor 46 that detects the physical quantity different from the physical quantity detected by the first inertial sensor 45. The third inertial sensor 46 is stored in the first package together with the first inertial sensor 45.

Accordingly, it is possible to provide the inertial measurement device 100 including the six-axis combo sensor that reduces the influence of moisture and that has excellent detection accuracy.

### Second Embodiment

### First Inertial Sensor Module in Different Mounting Form

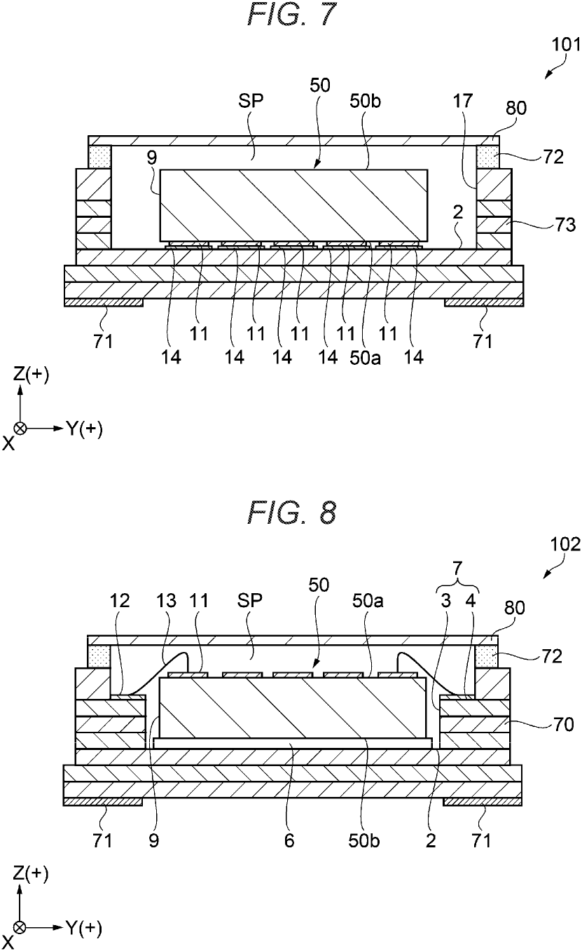

FIG. 7 is a cross-sectional view of a first inertial sensor module in a different mounting form, and corresponds to FIG. 2.

In the above-described embodiment, the first inertial sensor module 50 and the base 70 are coupled to each other by the bonding wires 13. The configuration is not limited thereto, and any configuration that allows electrical coupling between the two components may be used. For example, the first inertial sensor module 50 may be flip-chip mounted. Hereinafter, the same reference numerals are given to the same portions as those according to the above-described embodiment, and the redundant description thereof will be omitted.

In an inertial measurement device 101 in the present embodiment, the first inertial sensor module 50 is face-down mounted on a base 73.

First, in a concave portion 17 of the base 73, the peripheral edge portion 4 (FIG. 2) of the concave portion 7 of the base 70 in the first embodiment is not provided, and a storage space is larger than that of the concave portion 7. A plurality of coupling terminals 14 are provided on the placement surface 2 serving as the bottom portion of the concave portion 17. The plurality of coupling terminals 14 are disposed at positions corresponding to the electrode terminals 11 of the first inertial sensor module 50 in a plan view, and are electrically coupled to the mounting terminals 71 provided at a bottom surface of the base 73 by wirings, which are not shown, in the base 73.

In a preferable example, the electrode terminals 11 and the coupling terminals 14 are coupled by solder as a conductive material. Specifically, after a solder paste is applied to the plurality of coupling terminals 14, the first inertial sensor module 50 with the first surface 50a facing the placement surface 2 is mounted on the placement surface 2 and is soldered by heating. The conductive material is not limited to solder, and may be any material that can electrically couple the electrode terminals 11 and the coupling terminals 14. For example, gold bumps may be provided on the electrode terminals 11 and coupled to the gold-plated coupling terminals 14 by pressure contact or bonded to the coupling terminals 14 by ultrasonic welding. Alternatively, the gold bumps may be coupled to the electrode terminals 11 by soldering, or may be coupled by an adhesive containing anisotropic conductive particles instead of solder. In other words, the first inertial sensor module 50 is mounted on the placement surface 2 with the first surface 50a facing the concave portion 17, and the electrode terminals 11 and the coupling terminals 14 are coupled by the conductive material.

FIG. 8 is a cross-sectional view of a first inertial sensor module in a different mounting form, and corresponds to FIG. 2.

In the mounting form achieved by the bonding wires in FIG. 2, a spacer 6 may be provided between the placement surface 2 of the base 70 and the first inertial sensor module 50.

In an inertial measurement device 102 in the present embodiment, the plate-shaped spacer 6 is provided between the placement surface 2 of the base 70 and the first inertial sensor module 50. Other than this point, the components are the same as the inertial measurement device 100 according to the first embodiment.

In a preferable example, the spacer 6 is a silicon substrate, and has substantially the same size as the second surface 50b of the first inertial sensor module 50 in a plan view. The spacer 6 is fixed to the placement surface 2 of the base 70 and the second surface 50b of the first inertial sensor module 50 with an adhesive. A material of the spacer 6 is not limited to the silicon substrate, and may be any material that can serve as a stress buffering member between the placement surface 2 and the first inertial sensor module 50. For example, a ceramic substrate may be used, or an organic material such as a polyimide plate may be used.

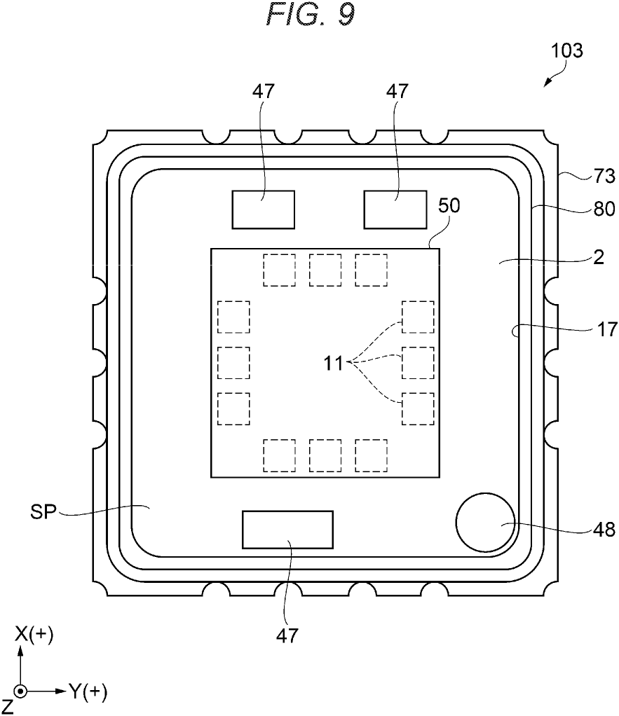

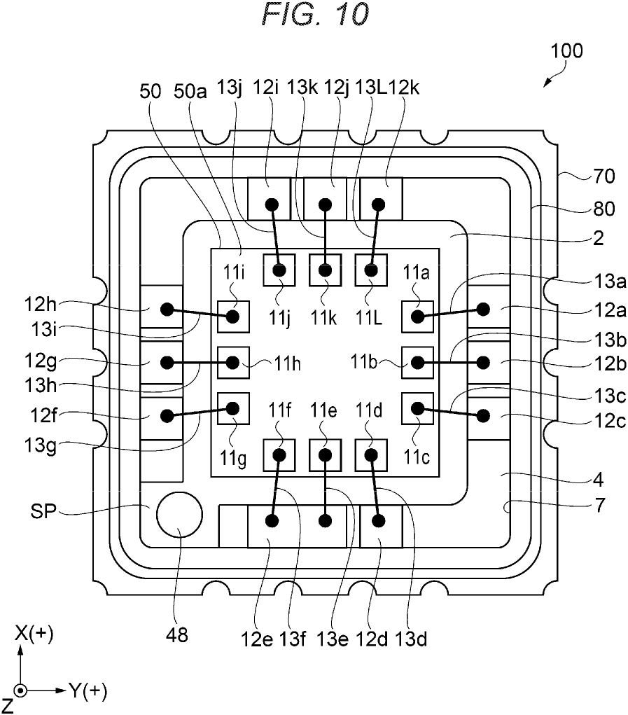

FIG. 9 is a plan view of an inertial measurement device in a different mounting form, and corresponds to FIGS. 1 and 7.

In the above description, the first inertial sensor module 50 is stored in the accommodation space SP of the inertial measurement device 100. The configuration is not limited thereto, and electronic components and the like may be stored together.

FIG. 9 is a transparent plan view when the first inertial sensor module 50 is face-down mounted on the base 73 described in FIG. 7.

In an inertial measurement device 103 in the present embodiment, in addition to the first inertial sensor module 50, three electronic components 47 are also mounted on the placement surface 2 of the base 73. Specifically, two electronic components 47 are mounted along the X-plus side of the placement surface 2 of the base 73. One electronic component 47 is mounted along the X-minus side of the placement surface 2.

The electronic component 47 is, for example, a chip capacitor, and functions as a bypass capacitor in terms of a circuit. Mounting terminals, which are not shown, corresponding to electrodes of the electronic components 47 are provided on the placement surface 2 of the base 73, and are electrically coupled to the first inertial sensor module 50 by wirings, which are not shown, in the base 73. The electronic component 47 is not limited to the chip capacitor, may be any electronic component that can be mounted on a surface, and may be, for example, a chip resistor or an integrated circuit (IC).

An adsorbent 48 is provided on the Y-plus side of the electronic component 47 disposed along the X-minus side of the placement surface 2. The adsorbent 48 is, for example, a gettering agent that adsorbs an organic solvent or moisture generated by solder melting when the first inertial sensor module 50 or the electronic component 47 is mounted. In a preferable example, an appropriate amount of the paste-shaped adsorbent 48 is applied to the placement surface 2. In other words, the electronic components 47 electrically coupled to the first inertial sensor module 50 are stored in the accommodation space SP. The adsorbent 48 serving as the gettering agent is also stored in the accommodation space SP. As the adsorbent 48, for example, calcium carbonate, barium oxide, barium, or a barium alloy, which functions as a moisture adsorbent, can be used. By adsorbing moisture by the adsorbent 48, corrosion of an activator contained in a solder flux can be prevented. When the base 70 and the lid 80 are brazed by the bonding member 72 containing magnesium, the magnesium is preferably used as the adsorbent 48. A material of the adsorbent 48 is not limited to these materials, and may be appropriately set according to a mounting method of a mounting component or a bonding method between the base 70 and the lid 80. An arrangement position of the adsorbent 48 is not limited to the above examples. For example, an appropriate amount may be applied to an inner surface side of the lid 80.

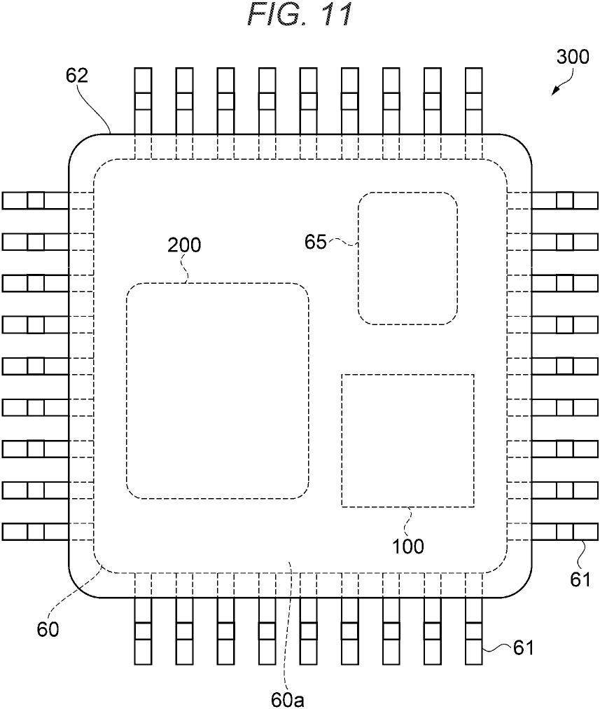

FIG. 10 is a plan view of an inertial measurement device in a different mounting form, and corresponds to FIG. 1.

In an inertial measurement device 104 according to the present embodiment, the adsorbent 48 is provided at a corner portion of the placement surface 2 of the base 70.

A part of one corner portion of the peripheral edge portion 4 is cut to form the placement surface 2 of the base 70. The adsorbent 48 is provided at the placement surface 2. As described above, the adsorbent 48 can be mounted also in the inertial measurement device 104 in a mounting mode using the bonding wires 13.

As described above, according to the inertial measurement devices 101 to 104 in the present embodiment, the following effects can be attained in addition to the effects according to the first embodiment.

According to the inertial measurement device 101, the first inertial sensor module 50 has the first surface 50a including the plurality of electrode terminals 11 and the second surface 50b which is an opposite-side surface from the first surface 50a. The plurality of coupling terminals 14 are provided at the placement surface 2 serving as the bottom portion of the concave portion 17. The first inertial sensor module 50 is mounted on the placement surface 2 in a state in which the first surface 50a faces the concave portion 17. The electrode terminals 11 and the coupling terminals 14 are coupled by a conductive material.

Accordingly, the first inertial sensor module 50 is hermetically sealed in the accommodation space SP between the ceramic base 73 and the metal lid 80. In other words, the first inertial sensor module 50 can be hermetically sealed in a ceramic package that can reliably prevent moisture from entering. Therefore, since it is possible to reliably prevent moisture from entering the inertial measurement device 101, it is possible to prevent stress variation of the resin 9 due to moisture entering.

Therefore, it is possible to provide the inertial measurement device 101 that reduces the influence of moisture and that has excellent detection accuracy. Further, since the first inertial sensor module 50 is face-down mounted on the base 73, a mounting area is reduced, and the inertial measurement device 101 can be miniaturized.

According to the inertial measurement device 102, the plate-shaped spacer 6 is disposed between the second surface 50b of the first inertial sensor module 50 and the placement surface 2.

Accordingly, for example, when the stress is applied to the base 70 from the outside, the spacer 6 including the adhesive on both surfaces serves as a buffer member, and it is possible to prevent the stress from being directly applied to the first inertial sensor module 50. Therefore, reliability of the inertial measurement device 102 can be improved.

According to the inertial measurement devices 103 and 104, the electronic components 47 electrically coupled to the first inertial sensor module 50 are stored in the accommodation space SP. The adsorbent 48 serving as the gettering agent is also stored in the accommodation space SP.

Accordingly, since the electronic components 47 can be disposed near the first inertial sensor module 50, the wiring is shortened, and an electrically stable circuit can be set. Further, since the adsorbent 48 is present in the accommodation space SP, when the first inertial sensor module 50 and the electronic components 47 are mounted, it is possible to adsorb an organic solvent or the like generated as the solder melts. Accordingly, it is possible to prevent the organic solvent and moisture that are diffused into the atmosphere in the package from being absorbed by the resin 9 of the first inertial sensor module 50. Therefore, it is possible to prevent the variation in the sensor characteristics due to the variation in the residual stress in the mold.

### Third Embodiment

### Inertial Measurement Device in Different Form-1

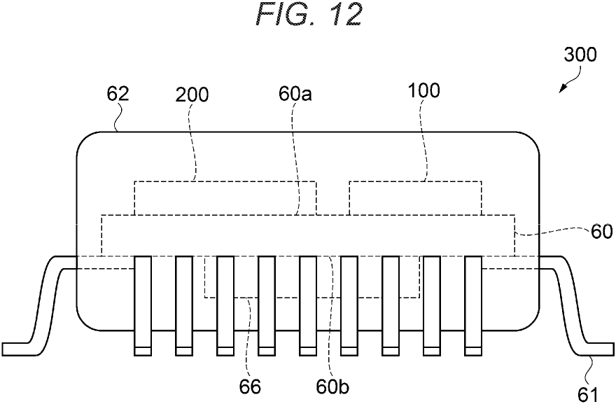

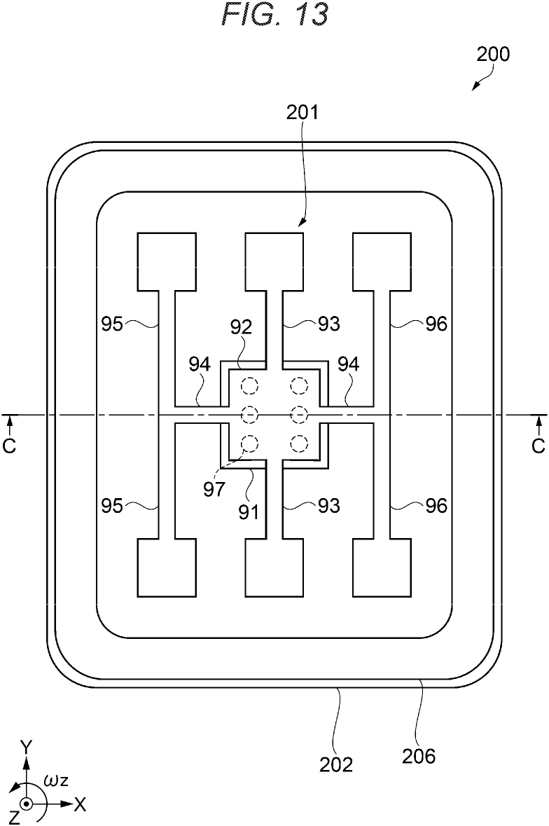

FIG. 11 is a plan view of an inertial measurement device in a different form. FIG. 12 is a cross-sectional view of the inertial measurement device in the different form.

The inertial measurement devices 100 to 104 described in the above embodiments can be applied to an inertial measurement device 300 used in a monitoring system of a building such as a bridge or an elevated track for which high accuracy is required. In the following description, the inertial measurement device 100 is referred to as an inertial measurement unit 100 as a representative of the inertial measurement devices 100 to 104. The same reference numerals are given to the same portions as those of the above-described embodiment, and the redundant description thereof will be omitted.

As shown in FIG. 11, the inertial measurement device 300 according to the present embodiment employs a lead frame type package including a plurality of mounting terminals 61 around the inertial measurement device 300.

The inertial measurement device 300 includes a base substrate 60, the inertial measurement unit 100, an inertial measurement unit 200, an oscillator 65, a resin 62, and the like. Although details will be described later, the detection accuracy of the inertial measurement unit 200 is higher than that of the inertial measurement unit 100. That is, the inertial measurement device 300 in the present embodiment includes two inertial measurement units 100 and 200 having different detection accuracies. The inertial measurement unit 200 is also referred to as a second inertial sensor module.

The inertial measurement unit 100, the inertial measurement unit 200, the oscillator 65, and the like are mounted on a front surface 60a of the base substrate 60. As shown in FIG. 12, a semiconductor element 66 is mounted on a back surface 60b of the base substrate 60.

The oscillator 65 is, for example, an oscillation circuit including a resonator element such as a quartz crystal resonator, and outputs a reference clock signal to the semiconductor element 66.

The semiconductor element 66 includes a drive circuit that drives the inertial measurement units 100 and 200, a detection circuit that detects angular velocities around three axes and accelerations in three-axis directions based on signals from the inertial measurement units 100 and 200, an output circuit that converts the signals from the detection circuit into a predetermined signal and that outputs the predetermined signal, and the like. The semiconductor element 66 controls a detection timing and a detection time of the angular velocity and the acceleration detected by the inertial measurement units 100 and 200 based on the clock signal from the oscillator 65.

The resin 62 is, for example, an epoxy resin, covers the inertial measurement units 100 and 200, the oscillator 65, and the semiconductor element 66, and resin-molds an exterior of the inertial measurement device 300.

### Configuration of Second Inertial Sensor Module

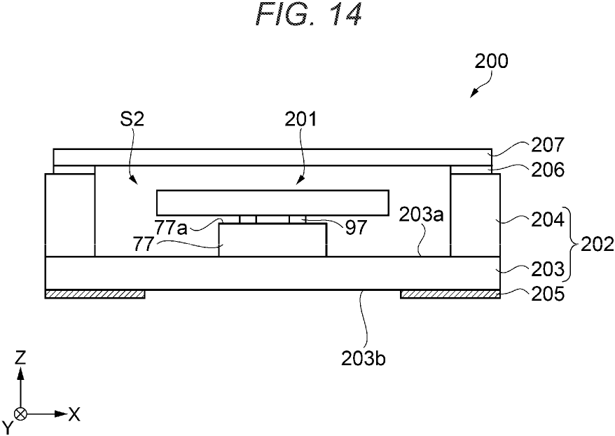

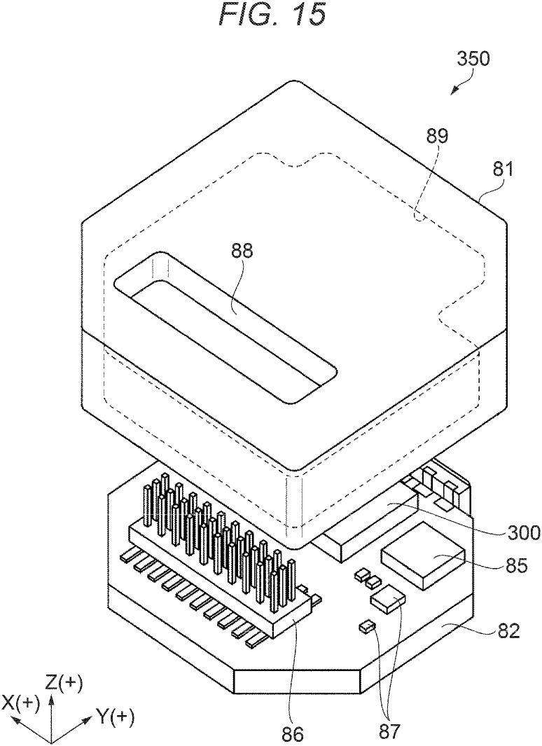

FIG. 13 is a transparent plan view of the second inertial sensor module. FIG. 14 is a cross-sectional view taken along a line C-C in FIG. 13.

Here, the configuration of the inertial measurement unit 200 serving as the second inertial sensor module will be described.

The inertial measurement unit 200 shown in FIG. 13 is a single-axis gyro sensor that includes a vibration gyro sensor element 201 and measures an angular velocity of a detection axis around a Z-axis serving as a third axis. The vibration gyro sensor element 201 is a gyro sensor element manufactured by processing a quartz crystal substrate using a photolithography technique, and converts vibration of a detection vibration arm into an electric signal to detect an angular velocity. Since the quartz crystal is used as the substrate, temperature characteristics are excellent. Therefore, as compared to the gyro sensor element manufactured using the MEMS technique, the vibration gyro sensor element 201 is less likely to be affected by external noise and temperature, and has high detection accuracy. That is, the detection accuracy of the inertial measurement unit 200 is higher than the detection accuracy of the inertial measurement unit 100.

As shown in FIGS. 13 and 14, the inertial measurement unit 200 includes the vibration gyro sensor element 201, a base 202 made of ceramic or the like that accommodates the vibration gyro sensor element 201, and a lid 207 made of glass, ceramic, metal, or the like.

The base 202 is formed by stacking a plate-shaped first substrate 203 and a frame-shaped second substrate 204. The base 202 has an accommodation space S2 that is open upward. The accommodation space S2 for accommodating the vibration gyro sensor element 201 is hermetically sealed in a depressurized state, preferably in a state close to a vacuum state, by bonding the lid 207 with a bonding member 206 such as a seal ring.

A convex portion 77 protruding upward is formed at an upper surface 203a of the first substrate 203 of the base 202, and the vibration gyro sensor element 201 is electrically and mechanically fixed to an upper surface 77a of the convex portion 77 via a metal bump 97 or the like. Therefore, contact between the vibration gyro sensor element 201 and the first substrate 203 can be prevented.

A plurality of mounting terminals 205 are provided at a lower surface 203b of the first substrate 203 of the base 202. The mounting terminals 205 are electrically coupled to the vibration gyro sensor element 201 via wirings which are not shown. The vibration gyro sensor element 201 corresponds to a second inertial sensor. In other words, a second package is formed by bonding the lid 207 to the base 202, and the vibration gyro sensor element 201 serving as the second inertial sensor is accommodated in the second package.

The vibration gyro sensor element 201 includes a base portion 92 located at a central portion, a pair of detection vibration arms 93 extending from the base portion 92 in the Y direction, a pair of coupling arms 94 extending from the base portion 92 in the X direction in a manner of being orthogonal to the detection vibration arms 93, and pairs of driving vibration arms 95 and 96 extending from tip end sides of the coupling arms 94 in the Y direction in a manner of being parallel to the detection vibration arms 93. The vibration gyro sensor element 201 is electrically and mechanically fixed to the upper surface 77a of the convex portion 77 provided at the base 202 via the metal bump 97 or the like in the base portion 92.

In the vibration gyro sensor element 201, when an angular velocity wz around the Z axis is applied in a state in which the driving vibration arms 95 and 96 are vibrating in a bending manner in the X direction in opposite phases, a Coriolis force in the Y direction acts on the driving vibration arms 95 and 96 and the coupling arms 94, and the vibration gyro sensor element 201 vibrates in the Y direction. Due to the vibration, the detection vibration arms 93 are bent and vibrated in the X direction. Therefore, the angular velocity wz is obtained by detection electrodes formed at the detection vibration arms 93 detecting distortion of the quartz crystal generated by the vibration as an electric signal.

In the present embodiment, the inertial measurement unit 200 is a single-axis gyro sensor capable of measuring the angular velocity around the Z-axis serving as the third axis. The inertial measurement unit 200 is not limited thereto, and may be a single-axis gyro sensor capable of measuring an angular velocity around the X axis serving as the first axis or an angular velocity around the Y axis serving as the second axis. The inertial measurement unit 200 may be a single-axis acceleration sensor capable of measuring an acceleration in the X direction serving as the first axis, an acceleration in the Y direction serving as the second axis, or an acceleration in the Z direction serving as the third axis. The inertial measurement unit 200 uses a sensor element using the quartz crystal as the substrate, and the inertial measurement unit 200 is not limited thereto. Any sensor may be used as long as the detection accuracy is higher than that of the inertial measurement unit 100.

The description returns to FIG. 11.

As described above, the inertial measurement unit 100, which is a first inertial measurement device including the inertial measurement device 100, and the inertial measurement unit 200, which is the second inertial sensor module, are mounted on the base substrate 60 to form the lead packaged inertial measurement device 300.

As described above, according to the inertial measurement device 300 in the present embodiment, the following effects can be attained in addition to the effects according to the above-described embodiments.

The inertial measurement device 300 further includes the inertial measurement unit 200 as the second inertial sensor module. The inertial measurement unit 200 includes the base substrate 60 as the substrate and the second package including the base 202 and the lid 207 that accommodates the vibration gyro sensor element 201 as the second inertial sensor. The inertial measurement unit 100 serving as the first inertial measurement device including the inertial measurement device 100 and the inertial measurement unit 200 serving as the second inertial sensor module are mounted on the base substrate 60.

Accordingly, since the inertial measurement unit 200 has higher detection accuracy than the inertial measurement unit 100 and has a detection axis around the Z axis, which is the third axis, it is possible to provide the inertial measurement device 300 having more excellent detection accuracy.

The first inertial sensor 45 of the inertial measurement unit 100 has the first axis, the second axis, and the third axis that are orthogonal to one another as detection axes. The vibration gyro sensor element 201 serving as the second inertial sensor has the third axis as the detection axis, and thus has higher detection accuracy than the detection accuracy of the first inertial sensor 45.

Accordingly, it is possible to provide the inertial measurement device 300 having more excellent detection accuracy.

### Fourth Embodiment

### Inertial Measurement Device in Different Form-2

FIG. 15 is an exploded perspective view showing an inertial measurement device in a different form.

The inertial measurement device 300 described in the above embodiment can be applied to an inertial measurement device 350 used in a monitoring system of a building such as a bridge or an elevated track in which high accuracy is required. The same reference numerals are given to the same portions as those according to the above-described embodiment, and the redundant description thereof will be omitted.

As shown in FIG. 15, the inertial measurement device 350 according to the present embodiment includes a connector 86 in order to be easily coupled to a measurement device, which is not shown, in a higher-level monitoring system. The inertial measurement device 350 includes a base substrate 82, a case 81, and the like.

The base substrate 82 is, for example, a rigid substrate such as a glass epoxy substrate. The inertial measurement device 300, a control IC 85, the connector 86, electronic components 87, and the like are mounted on the base substrate 82. The base substrate 82 has a substantially octagonal shape in a plan view, and the connector 86 is provided along one side of the base substrate 82.

The control IC 85 is a micro controller unit (MCU), and controls each unit of the inertial measurement device 350. A storage unit provided in the control IC 85 stores a program defining an order and contents for detecting an acceleration and an angular velocity, a program for digitizing detection data and incorporating the digitized detection data into packet data, accompanying data, and the like.

The connector 86 is, for example, a surface mounting type male connector including a plurality of coupling pins extending in a Z-plus direction.

The electronic component 87 is a circuit element such as a chip resistor or a chip capacitor.

The case 81 is a housing that covers and protects the base substrate 82, and an opening 88 for exposing the connector 86 is formed in an upper surface of the case 81. A concave portion 89 for storing the base substrate 82 on which the inertial measurement device 300 and the like are mounted is provided on a lower surface of the case 81. In a state in which the base substrate 82 is incorporated in the concave portion 89 of the case 81, for example, a female connector corresponding to the connector 86 can be coupled from the opening 88.

As described above, according to the inertial measurement device 350 in the present embodiment, the following effects can be attained in addition to the effects according to the above-described embodiments.

The inertial measurement device 350 includes a connector 86 for coupling to an external device.

Therefore, according to the inertial measurement device 350, the coupling with the measurement device which is not shown in a high-level monitoring system can be easily performed by the connector 86.

Therefore, it is possible to provide the inertial measurement device 350 with good usability.

Although the inertial measurement device 350 is mounted on the base substrate 82 in the above description, the inertial measurement device 100 (FIG. 1) and the inertial measurement device 200 (FIG. 11) may be mounted on the base substrate 82 instead of the inertial measurement device 350. As described above, the inertial measurement devices 100 and 200 can reliably prevent moisture from entering the inside even in this state, and thus can attain excellent detection accuracy.

What is claimed is:

1. An inertial measurement device comprising:
a first inertial sensor;
a first inertial sensor module in which the first inertial sensor is stored in a first package made of resin;
a base having a concave portion and made of ceramic; and
a lid body, wherein
the first inertial sensor module is accommodated in an accommodation space between the base and the lid body and is hermetically sealed.

2. The inertial measurement device according to claim 1, wherein
the base and the lid body are bonded to each other by welding.

3. The inertial measurement device according to claim 1, wherein
a gettering agent is stored in the accommodation space.

4. The inertial measurement device according to claim 1, wherein
an electronic component electrically coupled to the first inertial sensor module is stored in the accommodation space.

5. The inertial measurement device according to claim 1, wherein
the first inertial sensor module has a first surface including a plurality of electrode terminals and a second surface which is an opposite-side surface from the first surface,
the concave portion includes an accommodation portion having a placement surface as a bottom portion, and a peripheral edge portion that is one step higher than the placement surface and that surrounds the accommodation portion,
the first inertial sensor module is mounted on the placement surface in a state in which the second surface faces the concave portion,
a coupling terminal corresponding to the electrode terminal is provided in the peripheral edge portion, and
the electrode terminal and the coupling terminal of the peripheral edge portion are coupled to each other by a bonding wire.

6. The inertial measurement device according to claim 5, wherein
a plate-shaped spacer is disposed between the second surface of the first inertial sensor module and the placement surface.

7. The inertial measurement device according to claim 1, wherein
the first inertial sensor module has a first surface including a plurality of electrode terminals and a second surface which is an opposite-side surface from the first surface,
a plurality of coupling terminals are provided at a placement surface serving as a bottom portion of the concave portion,
the first inertial sensor module is mounted on the placement surface in a state in which the first surface faces the concave portion, and
the electrode terminals and the coupling terminals are coupled to each other by a conductive material.

8. The inertial measurement device according to claim 1, wherein
the first inertial sensor module further includes a third inertial sensor configured to detect a physical quantity different from a physical quantity detected by the first inertial sensor, and
the third inertial sensor is stored in the first package together with the first inertial sensor.

9. The inertial measurement device according to claim 1, further comprising:
a substrate; and
a second inertial sensor module including a second inertial sensor and a second package configured to accommodate the second inertial sensor, wherein
a first inertial measurement device including the inertial measurement device and the second inertial sensor module are mounted on the substrate.

10. The inertial measurement device according to claim 9, wherein
the first inertial sensor has a first axis, a second axis, and a third axis that are orthogonal to one another as detection axes, and
the second inertial sensor has the third axis as the detection axis and has detection accuracy higher than detection accuracy of the first inertial sensor.
